(19) United States
(12) Patent Application Publication
(10) Pub. No.: US 2026/0244837 A1
(43) Pub. Date: Aug. 20, 2026

(54) INTEGRATED CIRCUIT OPERABLE IN A PLURALITY OF DIFFERENT CONFIGURATIONS

(71) Applicant: Cirrus Logic International Semiconductor Ltd., Edinburgh (GB)

(72) Inventors: Monsoon DUTT, Newbury (GB); Mehul MISTRY, Newbury (GB)

(73) Assignee: Cirrus Logic International Semiconductor Ltd., Edinburgh (GB)

(21) Appl. No.: 19/055,033

(22) Filed: Feb. 17, 2025

(51) Int. Cl. G06F 30/34

(52) U.S. Cl. CPC G06F 30/34

(57) ABSTRACT

An integrated circuit (IC) operable in a plurality of different operating configurations, the IC comprising: a data input terminal; and processing circuitry, wherein the processing circuitry is configured to: process an input data frame received at the data input terminal to detect a predefined pattern of bits in the input data frame; and responsive to detecting the predefined pattern of bits in the input data frame, cause the IC to switch from a first operating configuration to a second operating configuration, wherein the processing circuitry is configured to process the input frame as if it were formatted according to a first data format, but the input data frame is formatted according to a second data format, different from the first data format.

### FIELD OF THE INVENTION

The present disclosure relates to an integrated circuit that is operable in a plurality of different configurations. The present disclosure further relates to a method for adjusting an operational configuration of an integrated circuit.

### BACKGROUND

General-purpose integrated circuits (ICs), e.g. analog to digital or digital to analog converter ICs, may be operable in multiple different configurations, to facilitate their use in different applications. For example, a general-purpose IC may support multiple different data input and/or output formats, such that in one configuration of the IC a first data input and/or output format is supported and in another configuration of the IC a second, different, data input and/or output format is supported.

Typically a desired configuration of such a general-purpose IC can be selected by means of a dedicated configuration selection terminal (e.g. a pin, pad, ball or the like) on a package containing or housing the IC. During manufacture of a device incorporating such a general-purpose IC, the dedicated configuration selection terminal is coupled to either a first known voltage supply (e.g. a positive power supply terminal of the IC) or a second known voltage supply (e.g. a 0V or negative power supply terminal of the IC). The state of the dedicated configuration selection terminal is determined during a power-up sequence of the IC and used to configure the IC. For example, if the dedicated configuration selection terminal is coupled to the first known voltage supply, the IC may adopt a first configuration, whereas if the dedicated configuration selection terminal is coupled to the second known voltage supply, the IC may adopt a second configuration.

However, in some cases it may be impossible or undesirable to provide a dedicated configuration selection terminal on an IC, for example if it is necessary or desirable to package the IC in a standard IC package that does not include sufficient terminals (e.g. pins, pads, balls or the like) to provide a dedicated configuration selection terminal.

Accordingly, a desire exists for an alternative means for selecting a configuration for an IC that is operable in a plurality of different configurations.

### SUMMARY

According to a first aspect, the invention provides an integrated circuit (IC) operable in a plurality of different operating configurations, the IC comprising: a data input terminal; and processing circuitry, wherein the processing circuitry is configured to: process an input data frame received at the data input terminal to detect a predefined pattern of bits in the input data frame; and responsive to detecting the predefined pattern of bits in the input data frame, cause the IC to switch from a first operating configuration to a second operating configuration, wherein the processing circuitry is configured to process the input frame as if it were formatted according to a first data format, but the input data frame is formatted according to a second data format, different from the first data format.

The IC may further comprise an interface enable terminal for receiving an interface enable signal, the interface enable signal being asserted to signal a start of the input data frame and de-asserted to signal an end of the input data frame. The processing circuitry may be operative to cause the IC to switch from the first operating configuration to the second operating configuration when the interface enable signal is de-asserted following detection of the predefined pattern of bits in the input data frame.

The IC may further comprise memory circuitry implementing a configuration register. The processing circuitry may be configured to interpret the predefined pattern of bits as comprising a register address and data to be written to the configuration register.

The processing circuitry may be operative to write the data to the configuration register to cause the IC to switch from the first operating configuration to the second operating configuration.

The processing circuitry may be operative to change a value of two or more configuration bits of the configuration register according to the data.

The plurality of different configurations may comprise a plurality of different interface formats for a communication protocol.

The communication protocol may comprise a serial peripheral interface (SPI) protocol.

The first data format may comprise eight address bits followed by one or more eight-bit data words. The second data format may comprise at least sixteen address bits followed by an eight-bit data word.

In operation of the IC in its first operational configuration, the processing circuitry may be operative to: interpret a first set of eight bits of the received data frame as address bits specifying a register address; interpret a second set of eight bits of the received data frame as data to be written to a register of the IC at the address specified by the address bits; and interpret a third set of eights bits of the received data frame as data to be written to a configuration register of the IC at an address subsequent to the address specified by the address bits.

The communication protocol may comprise an inter-integrated circuit (I2C) protocol.

The first operational configuration may be a default operational configuration of the IC.

According to a second aspect, the invention provides a method for adjusting an operational configuration of an integrated circuit (IC), the method comprising: receiving, at an IC, from circuitry external to the IC, a predefined pattern of bits, wherein the predefined pattern of bits is formatted as a data frame in a default data format of the circuitry external to the IC; processing, by the IC, the predefined pattern of bits as if it were formatted as a data frame in a default data format of the IC, wherein the default data format of the IC is different from the default data format of the circuitry external to the IC; and responsive to detection of the predefined pattern of bits by the IC, adjusting an operational configuration of the IC.

According to a third aspect, the invention provides an integrated circuit (IC) operable in a plurality of different configurations, the IC comprising: a data input terminal; and a configuration register for storing a configuration bit that defines an operational configurations of the IC, wherein the IC is configured to, responsive to receiving a predefined pattern of bits at the data input terminal, set the configuration bit in the configuration register according to a value received in the predefined pattern of bits.

According to a fourth aspect, the invention provides a method for switching between control interface formats in an integrated circuit (IC) that supports a plurality of different data interface formats, the method comprising: switching from a first data interface format to a second data interface format of the IC in response to receiving a predefined bit pattern at a data in terminal of the IC.

According to a fifth aspect, the invention provides a host device comprising the IC of the first aspect.

The host device may comprise for example, a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

According to a sixth aspect, the invention provides a system comprising: a first integrated circuit (IC) having an interface operable in a plurality of supported data formats, wherein one of the plurality of supported data formats is a default data format of the first IC; and a second IC communicatively coupled to the first IC, wherein the second IC is operable to transmit an initialisation command to the first IC in a supported data format other than the default data format of the first IC; and wherein the first IC is configured to process the initialisation command according to the default data format to determine a supported data format to be used for communication with the second IC.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a schematic representation of an integrated circuit (IC) according to the present disclosure;

FIG. 2 is a is a schematic representation of two example SPI data formats that are supported by the IC of FIG. 1 in one example of the present disclosure;

FIG. 3 shows signals received at an interface enable terminal, clock in terminal and a data in terminal of the IC of FIG. 1 while the IC is receiving a 24-bit serial peripheral interface (SPI) data frame in a second SPI format;

FIG. 4 shows an interface enable signal received at an interface enable terminal of the IC of FIG. 1, a clock signal received at the clock in terminal of the IC and a data signal received at the data in terminal of the IC when the IC is operating in a first configuration;

FIG. 5 shows an interface enable signal, a clock signal and a data out signal output by external circuitry to the IC of FIG. 1, and the data out signal as it is interpreted by the IC as a data in signal to the IC; and

FIG. 6 is a schematic representation of a system according to an aspect of the present disclosure.

### DETAILED DESCRIPTION

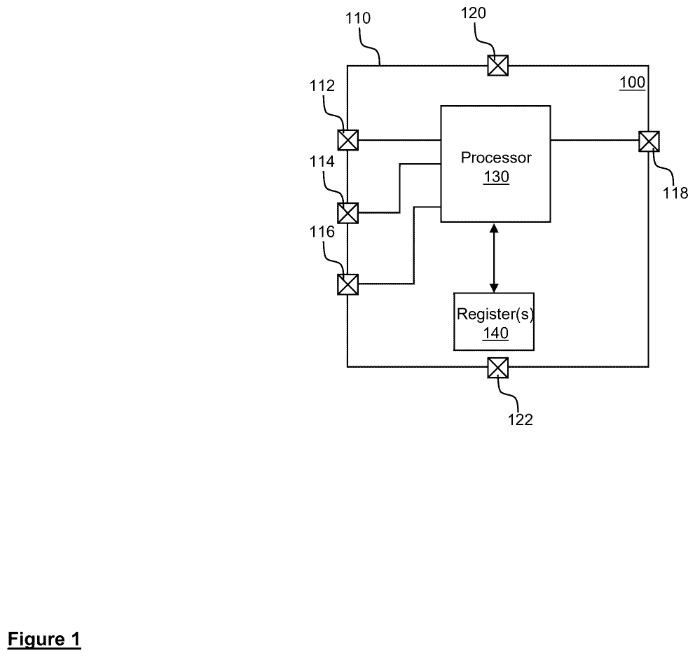

FIG. 1 is a schematic representation of an integrated circuit (IC) according to the present disclosure. The IC, shown generally at 100 in FIG. 1, may be a general-purpose IC that can be used in multiple different applications, such as an analog to digital converter (ADC) or digital to analog converter (DAC) IC, for example.

The IC 100 in the illustrated example comprises a package 110 having a data in terminal 112 for receiving input data to the IC 100, a clock in terminal 114 for receiving a clock signal, an interface enable terminal 116 (which may also be referred to as a chip select terminal) for receiving a signal indicative that a frame of data is being transmitted to the IC 100 via the data in terminal 112, and a data out terminal 118, for outputting data from the IC 100. The package 110 further includes a positive power supply terminal 120 for receiving a positive power supply voltage for the IC 100 and a reference power supply terminal 122 for receiving a reference voltage (e.g. 0V) for the IC 100. Each of the terminals 112, 114, 116, 118, 120, 122 may comprise an electrically conductive pin, pad, ball or the like, to enable them to be electrically coupled to circuitry external to the IC 100.

The IC 100 further comprises processing circuitry 130, and memory circuitry 140 implementing one or more registers. The processing circuitry 130 and memory circuitry 140 are housed within the package 110, and may be implemented on one or more die of semiconductor material such as silicon.

The processing circuitry 130 is coupled, internally of the package 110, to the data in terminal 112, the clock in terminal 114 and the interface enable terminal 116, to receive signals from each of those terminals, and to the data out terminal 118, to supply an output signal to the data out terminal 118. The processing circuitry 130 is also coupled, internally of the package 110, to the memory circuitry 140, for bidirectional data communication between the processing circuitry 130 and the memory circuitry 140.

The IC 100 is operable in a plurality of different configurations. However, in contrast to know ICs of the kind described above, no dedicated configuration selection terminal is provided on the IC 100 to facilitate selecting a configuration for the IC 100 from the plurality of different configurations. Instead, the configuration of the IC 100 is selected by transmitting a predefined pattern of bits to the data in terminal 112 of the IC 100. This predefined pattern of bits is interpreted by the IC 100 as an instruction to change the configuration of the IC 100.

In one example, the IC 100 is configured to support two or more formats for input and/or output of data. In a specific example, the IC 100 is configured to communicate with external circuitry (e.g. other integrated circuits) using the serial peripheral interface (SPI) standard, and is configured to support two SPI data formats, and/or two SPI control interface formats.

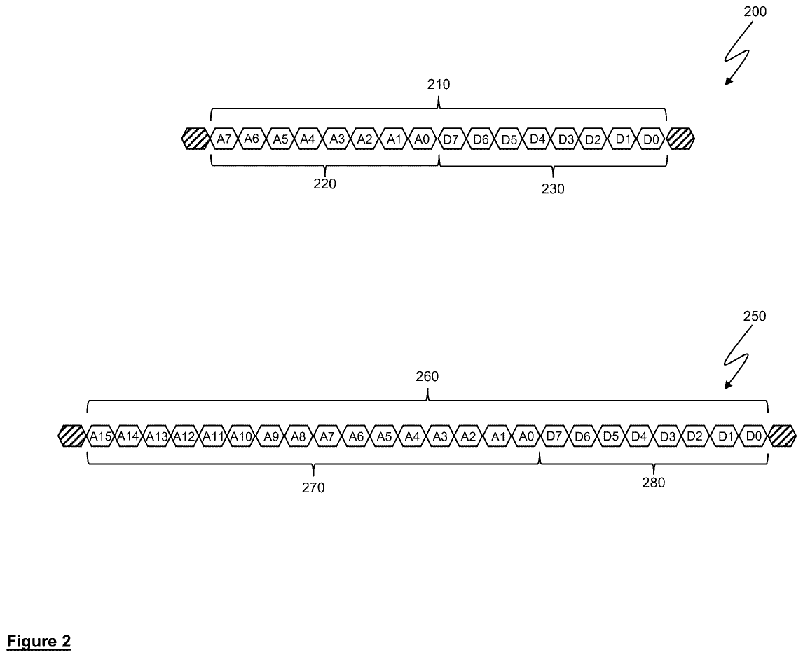

FIG. 2 is a schematic representation of two example SPI data formats that are supported by the IC 100 in one example.

In a first SPI data format, shown generally at 200 in FIG. 2, a 16 bit long SPI frame comprises an 8-bit address 220 (comprising 8 address bits A0-A7) followed by 8 bits of data 230 (shown as D0-D7). This data format may be referred to as a “banked format”.

In a second SPI data format, shown generally at 250 in FIG. 2, a 24 bit long SPI frame comprises a 16-bit address 260 (comprising 16 address bits A0-A15) followed by 8 bits of data 270 (shown as D0-D7). This data format may be referred to as a “flat format”.

In a first configuration of the IC 100, which may be a default configuration, the IC 100 may be configured to process received data as if it were transmitted in the first SPI format 200. Thus, in its first configuration, the IC 100 may “expect” input data to be formatted according to the first SPI format 200. In a second configuration of the IC 100, which may be a selectable configuration, the IC 100 may be configured to process received data as if it were transmitted in the second SPI format 250. Thus, in its second configuration, the IC 100 may “expect” input data to be formatted according to the second SPI format 250.

External circuitry (e.g. another IC) that supplies data to the IC 100 may be configured to output data in the second SPI format 250. Thus, if the IC 100 is operating in its first configuration, in which it processes received data as if it were transmitted in the first SPI format, the IC 100 must switch to its second configuration before data received from the external circuitry can be processed correctly by the IC 100.

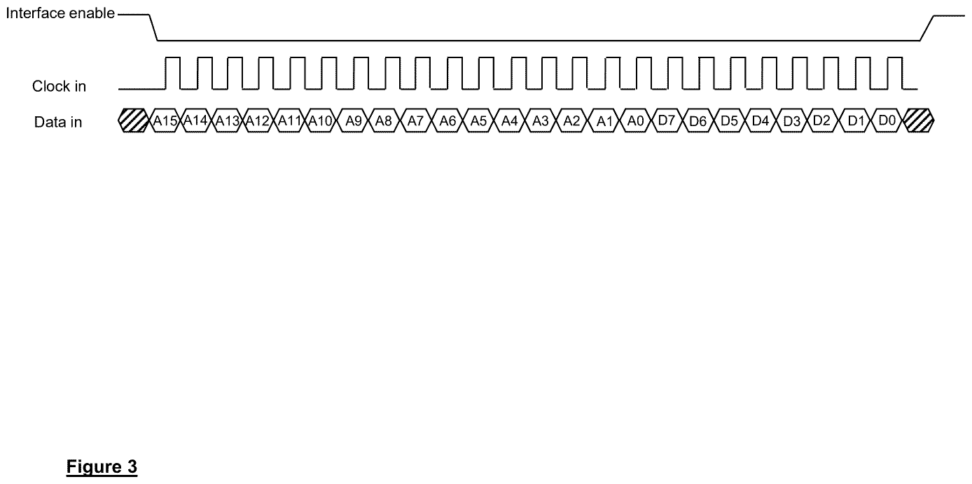

FIG. 3 shows signals received at the interface enable terminal 116, clock in terminal 114 and data in terminal 112 of the IC 100 while the IC is receiving a 24-bit SPI data frame, containing a single word of data, in the second SPI format.

In the example shown in FIG. 3, to signal the start of the SPI data frame, the circuitry transmitting the SPI data frame pulls an interface enable signal (which may also be referred to as a chip select signal) low, such that a signal received at the interface enable terminal 116 of the IC 100 transitions from a logic high signal level to a logic low signal level. One bit of the SPI data frame is then transmitted to the data in terminal 112 of the IC 100 per cycle of a clock signal that is received at the clock in terminal 114 of the IC 100. Thus, a complete SPI data frame (comprising the 16 address bits and the 8 data bits that make up the single data word of the SPI data frame) is received by the IC 100 over the course of 24 cycles of the clock signal. After 24 clock cycles, the circuitry transmitting the SPI data frame pulls the interface enable signal high to signal the end of the SPI data frame, such that the interface enable signal received at the interface enable terminal 116 of the IC 100 transitions from low to high.

A 16-bit SPI data frame, containing a single word of data, in the first SPI format can be transmitted to the IC 100 in a similar way, with the interface enable signal at the interface enable terminal 116 transitioning from a logic high signal level to a logic low signal level to signal the start of the SPI data frame, and one bit of the SPI data frame then being transmitted to the data in terminal 112 of the IC 100 per cycle of the clock signal, until all 16 bits of the SPI data frame (the 8 address bits and the 8 data bits making up the single data word) have been transmitted, at which point (i.e. after 16 clock cycles) the interface enable signal transitions from a logic low signal level to a logic high signal level to signal the end of the SPI data frame.

In the example shown in FIG. 3, the interface enable signal is an “active low” signal, meaning that the interface enable signal is considered to be active or asserted when it is at a low logic level. However, it will be appreciated that the interface enable signal could alternatively be an “active high” signal, meaning that the interface enable signal is considered to be active or asserted when it is at a high logic level, such that the start of an SPI data frame is signalled by the interface enable signal being pulled high by the transmitting circuitry, and the end of the SPI data frame is signalled by the interface enable signal being pulled low by the transmitting circuitry.

When the IC 100 is operating in its first configuration (i.e. expecting to receive a 16-bit SPI frame according to the first SPI format 200), the first 8 bits received by the IC 100 at its data in terminal 112 after the interface enable signal has been asserted (i.e. the first set of 8 bits received) are interpreted by the processing circuitry 130 as representing an address of a register (implemented in the memory circuitry 140) to which data is to be written, and the next 8 bits received by the IC 100 at its data in terminal 112 (i.e. the second set of 8 bits received) are interpreted by the processing circuitry 130 as data bits specifying a single word of data to be written to the register whose address is specified by the first 8 bits. Once the interface enable signal has been de-asserted (signalling the end of the SPI frame), the processing circuitry 130 writes the data defined by the 8 data bits to the register whose address is specified by the first 8 bits. This mode of operation may be referred to as a single word access mode.

If the interface enable signal remains asserted after 16 bits have been received by the IC 100 at the data in terminal 112 and additional bits are received at the received at the data in terminal 112 while the interface enable signal remains asserted, the IC 100 enters a multi-word access mode of operation, in which an internal address pointer is incremented every 8 bits.

In this mode, the first 8 bits received at the data in terminal 112 after the interface enable signal is asserted (i.e. a first set of 8 bits received by the IC 100) are interpreted by the processing circuitry 130 as representing an address of a first register (implemented in the memory circuitry 140) to which data is to be written. The next 8 bits received at the data in terminal 112 (i.e. a second set of 8 bits received by the IC 100) are interpreted by the processing circuitry 130 as representing a first single word of data to be written to the register whose address is specified by the first 8 bits received. The next 8 bits received at the data in terminal 112 (i.e. a third set of 8 bits received by the IC 100) are interpreted by the processing circuitry 130 as representing a second single word of data to be written to a register whose address is one greater than the address specified by the first set of 8 bits received.

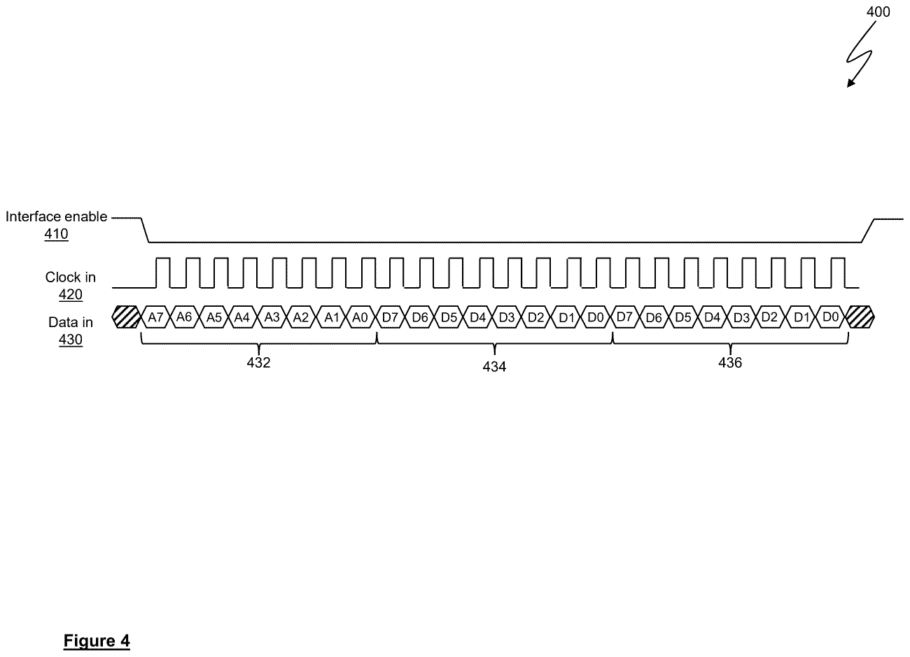

This is illustrated schematically in FIG. 4, which shows an interface enable signal 410 received at the interface enable terminal 116 of the IC 100, a clock signal 420 received at the clock in terminal 114 and a data signal 430 received at the data in terminal 112 when the IC 100 is operating in its first configuration such that a received data signal is interpreted as a 16-bit long SPI frame according to the first SPI format 200.

As shown in FIG. 4, while the interface enable signal 410 is asserted (low in this example), first, second and third sets of 8 bits 432, 434, 436 are received at the data in terminal 112 as part of the data signal 430.

The processing circuitry 130 of the IC 100 interprets the first set of 8 bits 432, (denoted in FIG. 4 as A7-A0, where A0 is the least significant bit) as an 8-bit address specifying the address of a register to which data is to be written. For example, if the values of the bits A7-A0 of the first set 432 were A7=0, A6=1, A5=0, A4=0, A3=0, A2=0, A1=0, A0=0, the processing circuitry 130 of the IC 100 would interpret the first set of 8 bits 432 as specifying that the address of a register to which data is to be written is 64.

The processing circuitry 130 of the IC 100 interprets the second set of 8 bits 434 (denoted in FIG. 4 as D7-D0, where D0 is the least significant bit) as a first 8-bit data word to be written to the address specified by the first set 432, e.g. address 64 in the example above. For example, if the values of the bits D7-D0 were D7=0, D6=0, D5=0, D4=0, D3=0, D2=0, D1=0, D0=0, the processing circuitry 130 would interpret the second set of 8 bits 434 as a value 0 to be written to the address specified by the first set 432, e.g. address 64.

As the interface enable signal 410 remains asserted after the second set of 8 bits 434 has been received at the data in terminal 112 of the IC 100, the processing circuitry 130 of the IC 100 interprets the third set of 8 bits 436 (denoted in FIG. 4 as D0-D7, where D0 is the least significant bit) as a second 8-bit data word to be written to the address immediately following the address specified by the first set 432, e.g. address 65, in the example above. For example, if the values of the bits D0-D7 of the third set 436 were D7=0, D6=0, D5=0, D4=0, D3=0, D2=0, D1=0, D0=1, the processing circuitry 130 would interpret the third set of 8 bits 436 as a value 1 to be written to the address immediately following the address specified by the first set 432, e.g. address 65.

This multi-word access mode of the IC 100 can be used to permit external circuitry that that is configured to output data in the second SPI format 250 to transmit a predefined bit pattern, formatted as if it were an SPI data frame according to the second SPI format 250, to cause the IC 100 to switch from its first configuration to its second configuration.

Consequently, no dedicated configuration selection terminal need be provided on the IC 100 to enable the operating configuration of the IC 100 to be changed.

Additionally, no special format is required for the external circuitry to transmit a command to the IC 100 to effect a change in the operating configuration of the IC 100. Instead, the external circuitry transmits the predefined bit pattern in its own native or default data format to the IC 100. The IC 100, in turn, processes the predefined bit pattern it receives from the external circuitry as if it were a data frame formatted in its own native or default data format, and changes its operating configuration accordingly.

Thus, in one example the external circuitry may transmit a predefined pattern of 24 bits in a format corresponding to the second SPI format 250. The IC 100 receives the transmitted bit pattern and processes it as if it were in the first SPI format 200.

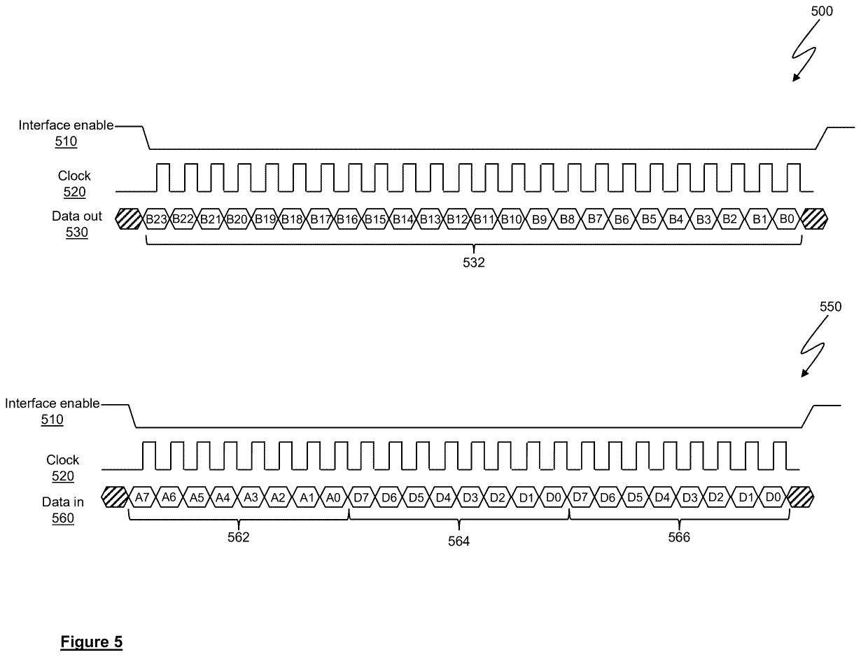

This is illustrated schematically in FIG. 5, which shows (at 500) an interface enable signal 510, a clock signal 520 and a data out signal 530 output by the external circuitry, and (at 550), the interface enable signal 510 and the clock signal 520 received by the IC 100. FIG. 5 also shows the data out signal 530 as it is interpreted by the IC 100 as a data in signal 560 to the IC 100.

As shown in FIG. 5, the external circuitry asserts the interface enable signal 510 (by pulling the interface enable signal 510 low in this example) and outputs the predefined bit pattern 532 as a sequence of 24 bits B0-B23, with one bit being output per cycle of the clock signal 520. When all the bits B0-B23 of the predefined bit pattern 532 have been output, the external circuitry de-asserts the interface enable signal 510 (by pulling the interface enable signal 510 high in this example). Thus, the external circuitry transmits the predefined bit pattern 532 in the same manner as it would transmit an SPI data frame formatted according to the second SPI format 250.

The IC 100 receives the interface enable signal 510 and the clock signal 520 from the external circuitry. The IC 100 also receives the data out signal 530 from the external circuitry as a data in signal 560. As shown in FIG. 5, the IC 100 “sees” the received data in signal 560 as an SPI data frame formatted according to the first SPI format 200. The processing circuitry 130 of the IC 100 thus interprets the first 8 bits of the received data in signal 560 (i.e. a first set 562 of 8 bits of the received data in signal 560) as an 8-bit address specifying the address of a register to which data is to be written. The processing circuitry 130 of the IC 100 interprets the next 8 bits of the received data in signal 560 (i.e. a second set 564 of 8 bits of the received data in signal 560) as an 8-bit data word to be written to the address specified by the first set 562 of 8 bits. As the interface enable signal 510 remains asserted (low) after the second set 564 of 8 bits has been received, the processing circuitry 130 of the IC 100 interprets the next 8 bits (i.e. a third set 566 of 8 bits of the received data in signal 560) as data to be written to a register having an address which is one greater than the address specified by the first set 562 of 8 bits.

The IC 100 processes the received data in signal 560 in the same way as it would process an SPI data frame when operating in its multi-word access mode. Thus, once the interface enable signal 510 has been de-asserted (reverted to a logic high signal level), the processing circuitry 130 of the IC 100 writes the data represented by the second set 564 of bits of the received data in signal 560 to a register (implemented in the memory circuitry 140) whose address corresponds to the value of the first set 562 of bits in the received data in signal 560, and writes the data represented by the third set 566 of bits of the received data in signal 560 to a register (implemented in the memory circuitry 140) having an address that is one greater than the value of the first set 562 of bits in the received data in signal 560.

It will be noted that the processing circuitry 130 only writes data to the registers after the interface enable signal 510 has been de-asserted (reverted to a logic high signal in the illustrated example). This ensures that the configuration of the IC 100 only changes after a data transaction between the external circuitry and the IC 100 has been completed, rather than changing during the data transaction, which could cause errors or other adverse effects.

As an example, if the value represented by the first set 562 of bits is 64, the value represented by the second set 564 of bits is 0, and the value represented by the third set 566 of bits is 1 (i.e. if the predefined bit pattern transmitted by the external circuitry to the IC 100 is [0 1 0 0 0 0 0 0 0 0 0 0 0 0 0 0 0 0 0 0 0 0 0 1]), the processing circuitry 130 writes a value of 0 to a register at address 64 and writes a value of 1 to a register at address 65.

The IC 100 is configured such that the register at the address to which the data represented by the third set 566 of bits of the received data in signal 560 (address 65 in the example discussed above) is a configuration register. Writing the data represented by the third set 566 of bits of the received data in signal 560 to this configuration register changes the value of one or more configuration bits that are stored in the configuration register, which has the effect of changing the configuration of the IC 100.

In the example discussed above, writing a value of 1 to the register at address 65 sets a configuration bit in that register, which has the effect of changing the IC 100 from its first configuration (in which the IC 100 is configured to process received data as if it were transmitted in the first SPI format 200) to its second configuration (in which the IC 100 is configured to processed received data as if it were transmitted in the second SPI format 250).

The IC 100 is configured, in the example discussed above, such that the register at the address to which the data represented by the second set 564 of bits of the received data in signal 560 (address 64 in the example discussed above) is unused, to ensure that writing the data represented by the second set 564 of bits of the received data in signal 560 does not adversely affect the operation of the IC 100.

In the example discussed above, the predefined bit pattern transmitted by the external circuitry to the IC 100 to effect a change in the operating configuration of the IC 100 is [0 1 0 0 0 0 0 0 0 0 0 0 0 0 0 0 0 0 0 0 0 0 0 1], but it will be appreciated that in practice the predefined bit pattern will be selected to suit a register map of the IC 100. The predefined bit pattern can therefore be any bit pattern that, when received by the IC 100, would be interpreted by the IC 100 as indicating an address of a register, a value to be written to a register at that address, and a value to be written to a register at a subsequent address.

Further, in the example discussed above, the predefined bit pattern [0 1 0 0 0 0 0 0 0 0 0 0 0 0 0 0 0 0 0 0 0 0 0 1] transmitted by the external circuitry to the IC 100 causes the processing circuitry 130 to write a value of 1 to the configuration register at address 65. Thus, in this example only one bit of the configuration register is changed in response to the IC 100 receiving the predefined bit pattern. In other examples, the predefined bit pattern may be selected so as to cause a change in two or more bits of the configuration register to effect a change in the operating configuration of the IC 100. For example, a predefined bit pattern of [0 1 0 0 0 0 0 0 0 0 0 0 0 0 0 0 0 0 0 1 0 1 0 1], when received by the IC 100, would cause the processing circuitry to write a value of 21 to a configuration register at address 65. Assuming the configuration register at address 65 initially stores a value of 0, this would result in three bits of the configuration register being changed. Such a bit pattern may be advantageous in applications in which a data channel between the external circuitry and the IC 100 is expected to be noisy, and/or in applications in which an unintended change in the operating confirmation of the IC 100 would have serious adverse effects, e.g. in safety critical applications, as it reduces the likelihood of an accidental change in the configuration of the IC 100 due to noise, because as the number of bits in the configuration register that must be changed to effect a change in the configuration of the IC 100 increase, the likelihood that noise will affect all these bits decreases.

In the example described above, the second SPI format 250 uses a 24-bit long SPI frame comprising a 16-bit address followed by 8 bits of data. In other examples, the second SPI format may comprise more than 16 address bits followed by 8 data bits In such examples, the external circuitry may transmit a predefined pattern of a length corresponding to the length of the SPI frame in the second SPI format 250, in a format corresponding to the second SPI format 250, to the IC 100 to effect a change in the operating configuration of the IC 100.

For example, if the second SPI format uses a 32 bit long SPI frame comprising a 24-bit address followed by 8 bits of data, the external circuitry will transmit a predefined pattern of 32 bits in length, e.g. [0 1 0 0 0 0 0 0 0 0 0 0 0 0 0 0 0 0 0 0 0 0 0 0 0 0 0 0 0 0 0 1] to effect a change in the operating configuration of the IC 100. To the external circuitry, this predefined pattern corresponds to 24 bits specifying an address of value 4194304, followed by 8 data bits making up a single data word of decimal value 1. On receiving this predefined pattern, the processing circuitry 130 of the IC 100, when operating in its first operating configuration, interprets the predefined pattern as a multi-word SPI frame made up of set of eight address bits specifying an address of 64, a first set of 8 data bits making up single data word of value of 0 to be written to address 64, a second set of 8 data bits making up a single data word of value 0 to be written to address 65 (the address whose value is one greater than the address specified by the 8 address bits), and a third set of 8 data bits making up a single data word of value 1 to be written to address 66 (the address whose value is two greater than the address specified by the 8 address bits). In this example, the configuration register storing the configuration bit that defines the operating configuration of the IC 100 is at address 66. Thus, once the predefined bit pattern has been received and the interface enable signal has been de-asserted, the processing circuitry 32 writes a value of 1 to the configuration register at address 66, to cause the IC 100 to switch to its second operating configuration.

In examples in which second SPI format comprises 24 address bits followed by 8 data bits, it is beneficial for the IC 100 to be configured such that the register at the address specified by the 8 address bits and the register at the address that is one greater than the address specified by the 8 address bits are unused, to ensure that writing the data represented by the first and second sets of data bits does not adversely affect the operation of the IC 100.

As another example, if the second SPI format uses a 40 bit long SPI frame comprising a 32-bit address followed by 8 bits of data, the external circuitry will transmit a predefined patter of 40 bits in length, e.g. [0 1 0 0 0 0 0 0 0 0 0 0 0 0 0 0 0 0 0 0 0 0 0 0 0 0 0 0 0 0 0 0 0 0 0 0 0 0 0 1] to effect a change in the operating configuration of the IC 100. To the external circuitry, this predefined pattern corresponds to 32 bits specifying an address of value 1073741824, followed by 8 data bits making up a single data word of decimal value 1. On receiving this predefined pattern, the processing circuitry 130 of the IC 100, when operating in its first operating configuration, interprets the predefined pattern as a multi-word SPI frame made up of set of eight address bits specifying an address of 64, a first set of 8 data bits making up single data word of value of 0 to be written to address 64, a second set of 8 data bits making up a single data word of value 0 to be written to address 65 (the address whose value is one greater address specified by the 8 address bits), a third set of 8 data bits making up a single data word of value 0 to be written to address 66 (the address whose value is two greater than the address specified by the 8 address bits), and a fourth set of 8 data bits making up a single data word of value 1 to be written to address 67 (the address whose value is three greater than the address specified by the 8 address bits). In this example, the configuration register storing the configuration bit that defines the operating configuration of the IC 100 is at address 67. Thus, once the predefined bit pattern has been received and the interface enable signal has been de-asserted, the processing circuitry 32 writes a value of 1 to the configuration register at address 67, to cause the IC 100 to switch to its second operating configuration.

In examples in which second SPI format comprises 32 address bits followed by 8 data bits, it is beneficial for the IC 100 to be configured such that the register at the address specified by the 8 address bits, the register at the address that is one greater than the address specified by the 8 address bits, and the register at the address that is two greater than the address specified by the 8 address bits are unused, to ensure that writing the data represented by the first, second and third sets of data bits does not adversely affect the operation of the IC 100.

In the examples described above, the data bits that define the value to be written to the configuration register of the IC 100 to effect a change in the operating configuration of the IC 100 are provided as the last set of 8 bits of the predefined bit pattern that is transmitted to the IC 100 by the external circuitry. However, in other examples, the data bits that define the value to be written to the configuration register of the IC 100 to effect a change in the operating configuration of the IC 100 could be provided at a different position in the predefined bit pattern, e.g. as the second set of 8 bits.

In such an example, the first set of 8 bits of the predefined bit pattern, when received by the IC 100 in its first operating configuration, are interpreted by the processing circuitry 130 as an address to which the set of 8 bits are to be written. The second set of 8 bits of the predefined bit pattern are interpreted as a set of 8 data bits defining a value to be written to the register at the address defined by the first set of 8 bits of the predefined bit pattern. The register at the address defined by the first set of 8 bits of the predefined bit pattern is a configuration register which stores one or more configuration bits that define the operating configuration of the IC 100.

As an example, in the case where the second SPI format comprises a 24-bit SPI frame comprising 16 address bits followed by 8 data bits, the external circuitry may transmit a predefined bit pattern of [0 1 0 0 0 0 0 0 0 0 0 0 0 0 0 1 0 0 0 0 0 0 0 0] to the IC 100. In this example, with the IC 100 operating in its first operating configuration, the processing circuitry 130 interprets the received bit pattern as a multi-word frame in the first SPI format, comprising a first set of 8 address bits defining an address (64) of a register to which to write a data word, a first set of 8 data bits defining a first data word to be written to the address defined by the address bits, and a second set of 8 data bits defining a second data word to be written to the address whose value is one greater than the value of the address defined by the first set of address bits.

The processing circuitry 130 in this example thus writes a value of 1 to a register at address 64, and writes a value of 0 to a register at address 65, once the interface enable signal has been de-asserted to signal the end of the SPI data frame. The register at address 64 is a configuration register which stores configuration bits that define the operating configuration of the IC 100, such that writing the value of 1 to the register at address 64 effects a change in the operating configuration of the IC 100.

The examples above refer to the SPI protocol, but it will be appreciated by those of ordinary skill in the art that the principles of the present disclosure can equally be employed to effect a change between data formats of other data transfer protocols, e.g. to switch between 7-bit, 8-bit and 10-bit addressing formats in the I2C (Inter-Integrated Circuit) protocol.

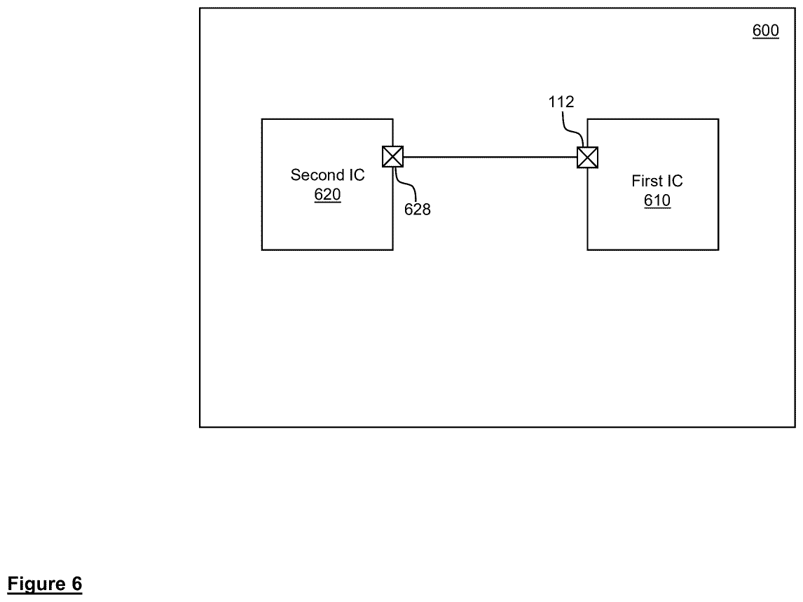

FIG. 6 is a schematic representation of a system according to an aspect of the present disclosure.

The system, shown generally at 600 in FIG. 6, comprises a first IC 610 and a second IC 620. The first IC 610 is an IC of the kind described above with reference to FIG. 1, and thus has a data in terminal 112 for receiving input data. Although not shown in FIG. 6 for the sake of clarity, it is to be understood that the first IC 610 may further include other input and/or output terminals of the kind described above with reference to FIG. 1, e.g. a clock in terminal for receiving a clock signal, an interface enable terminal (which may also be referred to as a chip select terminal) for receiving a signal indicative that a frame of data is being transmitted to the first IC 610 via the data in terminal 112, and a data out terminal, for outputting data from the first IC 610, as well as positive and reference power supply terminals of the and processing circuitry and memory of the kind described above with reference to FIG. 1.

The data in terminal 112 of the first IC 610 is electrically coupled to a data out terminal 628 of the second IC 620 (e.g. by a conductive trace on a substrate such as a printed circuit board (PCB) on which the first and second ICs 610, 620 are mounted) such that the first IC 610 can receive data from the second IC 620.

The first IC 610 is configured to support a plurality of formats for receiving and transmitting data. The first IC 610 thus has an interface for receiving and/or transmitting data that is operable according to a plurality of data formats supported by the first IC 610. For example, the first IC 610 may be configured to support the first and second SPI data formats 200, 250 described above with reference to FIG. 2.

The first IC 610 may be configured such that one of the supported data formats is a default or native data format, such that when operating in a first or default configuration, the first IC 610 “expects” to receive data in that format and processes data received at its data in terminal 112 as if it were received in the default or native format. The first IC 610 is reconfigurable to operate in a second configuration in which it processes received data as if it were received in a different one of the plurality of formats.

In this example, the first IC 610 is configured such that the first SPI data format 200 is its default or native format for receiving, processing and transmitting data, but can be reconfigured to receive, process and transmit data in the second SPI data format 250 in the manner described above with reference to FIGS. 4 and 5, by transmitting to the first IC 610 a predefined pattern of bits to change the value of one or more configuration bits that are stored in a configuration register of the first IC 610.

The second IC 620 may be configured to support one or more formats for transmitting and receiving data. The second IC 620 thus has an interface for receiving and/or transmitting data that is operable according to one or more data formats supported by the second IC 620. For example, the second IC 620 may be configured to support the second SPI data format 250 described above with reference to FIG. 2 (and may also support the first SPI data format 200). The second IC 620 may be configured such that one of the one or more supported data formats is a default or native data format, such that the second IC 620 transmits data formatted according to that format by default, and will only transmit data formatted according to another format if reconfigured to do so. In this example, the second IC 620 is configured such that the second SPI data format is its default or native format for transmitting and receiving data.

Thus, in this example, in order for the first IC 610 to process data received from the second IC 620 correctly, the first IC 610 must be reconfigured from its first configuration in which it processes received data according to its default or native data format (the first SPI data format, in this example) to a second configuration in which it processes received data according to the second SPI data format.

To this end, the second IC 620 is operative to transmit an initialisation command to the first IC 610, via the data connection between its data out terminal 628 and the data in terminal 112 of the first IC 610. The initialisation command takes the form of a predefined pattern of bits, formatted in this example as a 24-bit data frame according to the second SPI format. For example, the initialisation command may be the bit pattern [0 1 0 0 0 0 0 0 0 0 0 0 0 0 0 0 0 0 0 0 0 0 0 1]. In the second SPI data format, this bit pattern represents a 16-bit address (of value 16384 in this example) followed by an 8-bit data word (of value 1 in this example). However, the first IC 610, when operating in its first configuration in which received data is processed according to its default or native data format, interprets this bit pattern as representing an 8-bit address (of value 64) followed by a first 8-bit data word (of value 0) and a second 8-bit data word (of value 1).

On receiving the initialisation command, the first IC 610 processes it as if it had been transmitted according to its own native or default data format. Thus (as described above with reference to FIGS. 4 and 5), if an initialisation command in the form of the bit pattern [0 1 0 0 0 0 0 0 0 0 0 0 0 0 0 0 0 0 0 0 0 0 0 1] is received by the first IC 610 from the second IC 620, the first IC 610 writes the value 0 to a register at address 64 and writes the value 1 to a configuration register at address 65. Responsive to this change in the value of the configuration register, the first IC 610 determines that it is to operate in a second configuration in which it processes received data as if it were formatted according to the second SPI data format 250. The first IC 610 thus switches to operating in the second configuration, such that subsequent data transmissions from the second IC 620 in the second SPI data format 250 can be correctly processed by the first IC 610.

Thus, in the system 600 described above with reference to FIG. 6, the second IC 620 is operable to transmit an initialisation command to the first IC 610 in a data format that is supported by the first IC 610, but is not the native or default data format of the first IC 610 (i.e. the initialisation command is transmitted by the second IC 620 in a data format other than the native or default data format of the first IC 610) and the first IC 610 is configured to process the initialisation command according to its own native or default data format, to determine a supported data format to be used for communication with the second IC 620.

As will be appreciated by those of ordinary skill in the art, different initialisation commands received by the first IC 610 may be interpreted differently by the first IC 610. For example, responsive to an initialisation command that causes a value other than 1 to be written to the configuration register, the first IC 610 may determines that it is to operate in a further different configuration in which it processes received data as if it were formatted according to a further different data format, and may switch to operating in that further different configuration, such that subsequent data transmissions from the second IC 620 in the second SPI data format 250 can be correctly processed by the first IC 610.

The examples above refer to the SPI protocol, but it will be appreciated by those of ordinary skill in the art that the principles of the present disclosure can equally be employed to effect a change between data formats of other data transfer protocols, e.g. to switch between 7-bit, 8-bit and 10-bit addressing formats in the I2C (Inter-Integrated Circuit) protocol. The circuitry described above with reference to the accompanying drawings may be incorporated in a host device such as a laptop, notebook, netbook or tablet computer, a gaming device such as a games console or a controller for a games console, a virtual reality (VR) or augmented reality (AR) device, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. An integrated circuit (IC) operable in a plurality of different operating configurations, the IC comprising:
a data input terminal; and
processing circuitry,
wherein the processing circuitry is configured to:
process an input data frame received at the data input terminal to detect a predefined pattern of bits in the input data frame; and
responsive to detecting the predefined pattern of bits in the input data frame, cause the IC to switch from a first operating configuration to a second operating configuration,
wherein the processing circuitry is configured to process the input frame as if it were formatted according to a first data format, but the input data frame is formatted according to a second data format, different from the first data format.

2. The IC of claim 1, further comprising an interface enable terminal for receiving an interface enable signal, the interface enable signal being asserted to signal a start of the input data frame and de-asserted to signal an end of the input data frame,
wherein the processing circuitry is operative to cause the IC to switch from the first operating configuration to the second operating configuration when the interface enable signal is de-asserted following detection of the predefined pattern of bits in the input data frame.

3. The IC of claim 1, further comprising memory circuitry implementing a configuration register, wherein the processing circuitry is configured to interpret the predefined pattern of bits as comprising a register address and data to be written to the configuration register.

4. The IC of claim 3, wherein the processing circuitry is operative to write the data to the configuration register to cause the IC to switch from the first operating configuration to the second operating configuration.

5. The IC of claim 4, wherein the processing circuitry is operative to change a value of two or more configuration bits of the configuration register according to the data.

6. The IC of claim 1, wherein the plurality of different configurations comprise a plurality of different interface formats for a communication protocol.

7. The IC of claim 6, wherein the communication protocol comprises a serial peripheral interface (SPI) protocol.

8. The IC of claim 7, wherein:
the first data format comprises eight address bits followed by one or more eight-bit data words; and
the second data format comprises at least sixteen address bits followed by an eight-bit data word.

9. The IC of claim 8, wherein in operation of the IC in its first operational configuration, the processing circuitry is operative to:
interpret a first set of eight bits of the received data frame as address bits specifying a register address;
interpret a second set of eight bits of the received data frame as data to be written to a register of the IC at the address specified by the address bits; and
interpret a third set of eights bits of the received data frame as data to be written to a configuration register of the IC at an address subsequent to the address specified by the address bits.

10. The IC of claim 6, wherein the communication protocol comprises an inter-integrated circuit (I2C) protocol.

11. The IC of claim 1, wherein the first operational configuration is a default operational configuration of the IC.

12. A method for adjusting an operational configuration of an integrated circuit (IC), the method comprising:
receiving, at an IC, from circuitry external to the IC, a predefined pattern of bits, wherein the predefined pattern of bits is formatted as a data frame in a default data format of the circuitry external to the IC;
processing, by the IC, the predefined pattern of bits as if it were formatted as a data frame in a default data format of the IC, wherein the default data format of the IC is different from the default data format of the circuitry external to the IC; and
responsive to detection of the predefined pattern of bits by the IC, adjusting an operational configuration of the IC.

13. An integrated circuit (IC) operable in a plurality of different configurations, the IC comprising:
a data input terminal; and
a configuration register for storing a configuration bit that defines an operational configurations of the IC,
wherein the IC is configured to, responsive to receiving a predefined pattern of bits at the data input terminal, set the configuration bit in the configuration register according to a value received in the predefined pattern of bits.

14. A method for switching between control interface formats in an integrated circuit (IC) that supports a plurality of different data interface formats, the method comprising:
switching from a first data interface format to a second data interface format of the IC in response to receiving a predefined bit pattern at a data in terminal of the IC.

15. A host device comprising the IC according to claim 1.

16. A host device according to claim 15, wherein the host device comprises a laptop, notebook, netbook or tablet computer, a gaming device, a games console, a controller for a games console, a virtual reality (VR) or augmented reality (AR) device, a mobile telephone, a portable audio player, a portable device, an accessory device for use with a laptop, notebook, netbook or tablet computer, a gaming device, a games console a VR or AR device, a mobile telephone, a portable audio player or other portable device.

17. A system comprising:
a first integrated circuit (IC) having an interface operable in a plurality of supported data formats, wherein one of the plurality of supported data formats is a default data format of the first IC; and
a second IC communicatively coupled to the first IC,
wherein the second IC is operable to transmit an initialisation command to the first IC in a supported data format other than the default data format of the first IC; and
wherein the first IC is configured to process the initialisation command according to the default data format to determine a supported data format to be used for communication with the second IC.
